(19) United States
(12) Patent Application Publication
(10) Pub. No.: US 2007/0103200 A1
(43) Pub. Date: May 10, 2007

(54) Buffer circuit and use thereof

(76) Inventor: Mojtaba Joodaki, Dresden (DE)

Correspondence Address: SLATER & MATSIL LLP, 17950 PRESTON ROAD, SUITE 1000, DALLAS, TX, 75252, US

(21) Appl. No.: 11/584,242

(22) Filed: Oct. 20, 2006

(30) Foreign Application Priority Data
Oct. 21, 2005 (DE) 10 2005 050 624.0

(51) Int. Cl. H03K 19/094

(52) U.S. Cl. 326/87

(57) ABSTRACT

A buffer circuit includes a signal input, a first and a second voltage tap and an inverter circuit including an inverter input coupled to the signal input, an output node and a first and a second supply tap. Furthermore, a first element having a diode-type transfer response is provided, which is coupled by an anode terminal to the first supply tap. The buffer circuit correspondingly includes a second element, which is coupled by a cathode terminal to the second supply tap. Furthermore, a transistor pair is provided, wherein a control terminal of a first transistor of the transistor pair is coupled to the anode terminal of the first element and a control terminal of a second transistor of the transistor pair is coupled to the cathode terminal of the second element.

This application claims priority to German Patent Application 10 2005 050 624.0, which was filed Oct. 21, 2005 and is incorporated herein by reference.

### TECHNICAL FIELD

The invention relates to a buffer circuit and to a use thereof.

### BACKGROUND

Buffer circuits, in particular buffer circuits using complementary circuit technology (CMOS), are used for a multiplicity of digital circuits and are also referred to as push-pull circuits or as inverters for simplification. FIG. 5 shows a known example of a buffer circuit constructed from complementary field effect transistors for signal inversion. The buffer circuit illustrated comprises two series-connected field effect transistors T1, T2 of different conductivity types, which are coupled between two supply terminals VA1, VA2. The circuit is fed with a supply voltage via the two supply terminals.

A connection node of the two transistors T1, T2 forms the output tap A for the output signal. In the present case, the signal present at the input E controls the switching behavior of the transistors T1, T2 and thus the voltage drop across the latter. A level of the output signal that can be tapped off at the output A is inverted with respect to the input signal level given a suitable choice of the potentials at the terminals VA1 and VA2. The output signal thus changes between a level referred to as logic low and a level referred to as logic high.

Input signals having a high amplitude may, however, lead to a breakdown between the control terminal and the sink terminal of the transistors. A particularly complicated and expensive process technology is thus required for high-voltage applications. Undesired process fluctuations during the production of the individual transistors may adversely affect the changeover point of the output signal between a high and a low level, with the result that a changeover takes place at undesired values or the current consumption rises overall if both transistors are in the on state.

### SUMMARY OF THE INVENTION

According to an embodiment a buffer circuit comprises a signal input, a first transistor pair with a first and a second transistor, a first voltage tap and a second voltage tap. The first transistor is connected in series with the second transistor, their control terminals being coupled to the signal input. Furthermore, a first and a second element having a diode-type transfer response are provided. An anode terminal of the first element is coupled to the first transistor. A cathode terminal of the second element is correspondingly coupled to the second transistor. Furthermore, a further transistor pair with a third transistor and a fourth transistor connected in series is provided, wherein a control terminal of the third transistor is coupled to the anode terminal of the first element and a control terminal of the fourth transistor is coupled to the cathode terminal of the second element.

The configuration with elements having a diode-type transfer response at the terminals of the first transistor pair results in an increase in a breakdown voltage, so that the circuit is suitable even for applications having high input amplitudes. Moreover, the linearity of the transfer response is improved. By virtue of the second transistor pair, a linearity in the transfer characteristic curve is improved further and a higher driver capability is also achieved. At the same time, a parasitic capacitance of the circuit decreases as a result of the arrangement of the third transistor and the fourth transistor. As a result, the power consumption of the circuit is reduced and the efficiency and the current-carrying capacity are improved.

### BRIEF DESCRIPTION OF THE DRAWINGS

The invention is explained in detail below on the basis of various exemplary embodiments with reference to the drawings. In the figures:

FIG. 1 shows a first embodiment of a buffer circuit using complementary field effect transistor technology;

FIG. 2 shows a second embodiment of a buffer circuit;

FIG. 3 shows an exemplary voltage-current diagram for illustrating the transfer response of a conventional buffer circuit and of the embodiment of FIG. 1 or 2;

FIG. 4 shows an exemplary time-current diagram for illustrating the lower parasitic capacitance of the embodiment of FIG. 1 or 2 compared with a conventional buffer circuit; and

FIG. 5 shows an embodiment of a conventional buffer circuit.

### DETAILED DESCRIPTION OF ILLUSTRATIVE EMBODIMENTS

In the following description further aspects and embodiments of the present invention are summarized. In addition, reference is made to the accompanying drawings, which form a part hereof, and in which is shown by way of illustration, in which the invention may be practiced. The embodiments of the drawings present a summary in order to provide a better understanding of one or more aspects of the present invention. This summary is not an extensive overview of the invention and neither intended to limit the features or key-elements of the invention to a specific embodiment. Rather, the different elements, aspects and features disclosed in the embodiments can be combined in different ways by a person skilled in the art to achieve one or more advantages of the present invention. It is to be understood that other embodiments may be utilized and structural or logical changes may be made without departing from the scope of the present invention. The elements of the drawing are not necessarily to scale relative to each other. Like reference numerals designate corresponding similar parts.

In one embodiment a first transistor pair with a first transistor and a second transistor connected in series therewith, the transistors having different conductivity types, are coupled with their respective control terminals to a signal input. First terminals of the first and second transistors are coupled to one another at an output node. Furthermore, a first controllable path is provided, which is coupled with a first terminal to a first voltage tap for supply and with its second terminal on the one hand to its control terminal and also to the second terminal of the first transistor. A second controllable path is coupled to a second voltage tap with a first terminal and with its second terminal as well to its control terminal as to the second terminal of the second transistor.

A second transistor pair is coupled between the first and second voltage taps for its supply. The second transistor pair has a third transistor and a fourth transistor connected in series. A control terminal of the third transistor is coupled to the control terminal of the first controllable path and a control terminal of the fourth transistor is coupled to the control terminal of the second controllable path. A node between the third and fourth transistors is coupled to the output node between the first and second transistors.

By virtue of the second transistor pair, a linearity in the transfer characteristic curve is improved further and a higher driver capability is also achieved. At the same time, a parasitic capacitance decreases as a result of the third transistor being arranged in parallel with the first controllable path and the fourth transistor being arranged in parallel with the second controllable path. As a result, the power consumption of the circuit is reduced and the efficiency and the current-carrying capacity are improved further.

In one aspect of an embodiment, the first controllable path has the same conductivity type as the first transistor and the second controllable path has the same conductivity type as the second transistor.

The feedback in the first and second controllable paths as a result of the respective control terminal being coupled to the second terminal corresponds to an embodiment as an element having a diode-type transfer response. Therefore, in one embodiment, the first and second controllable paths can be implemented by a diode. In an alternative configuration, the first and second controllable paths are in each case embodied as field effect transistors whose sink terminals are coupled to the respective control terminal.

Consequently, in a buffer circuit, a first transistor pair with a first transistor and a series-connected second transistor is coupled with their control terminals to a signal input of the buffer circuit. The first transistor has a first conductivity type and the second transistor has a second conductivity type. Furthermore, a first element having a diode-type transfer response is provided, which is coupled with a cathode terminal to the first transistor. A second element, likewise having a diode-type transfer response, is coupled with its anode terminal to the second transistor. The first and second elements may in turn be coupled by their respective other terminal to a supply potential node.

The special configuration with additional elements having a diode-type transfer response at the terminals of the first transistor pair results in an increase in a breakdown voltage, so that the circuit illustrated is suitable even for applications having high input amplitudes. Moreover, the linearity of the transfer response is improved.

In another embodiment, the third and the first transistor, and the second and the fourth transistor comprise in each case the same conductivity type. In another configuration, the first transistor is embodied by means of a p-channel field effect transistor and the second transistor is embodied by means of an n-channel field effect transistor. It is likewise possible, of course, to interchange the conductivity type of the transistors. In a further embodiment at least the first transistor and the second transistor in each case comprise a substrate terminal coupled to the respective source terminal.

The series circuit comprising the controllable paths and the first transistor pair makes it possible to reduce a channel length of all the transistors used or at least of the first transistor pair. Thus, in one embodiment, the transistors have a channel length within the range of 60 to 120 nanometers. In another embodiment, the channel length is 70 to 90 nanometers. The configuration furthermore permits the alteration of individual parameters of the transistors, for example the doping, the channel width or the channel length. As a result, it is possible in a simple manner for the current-carrying capacity and also the changeover instant of the buffer circuit to be altered more easily and in different ways depending on the input signal and thus be adapted to the respective application. Random process fluctuations have a lesser effect on the transfer response. The buffer circuit according to the invention is suitable for use in memories, memory modules, but also in all integrated circuits for signal processing.

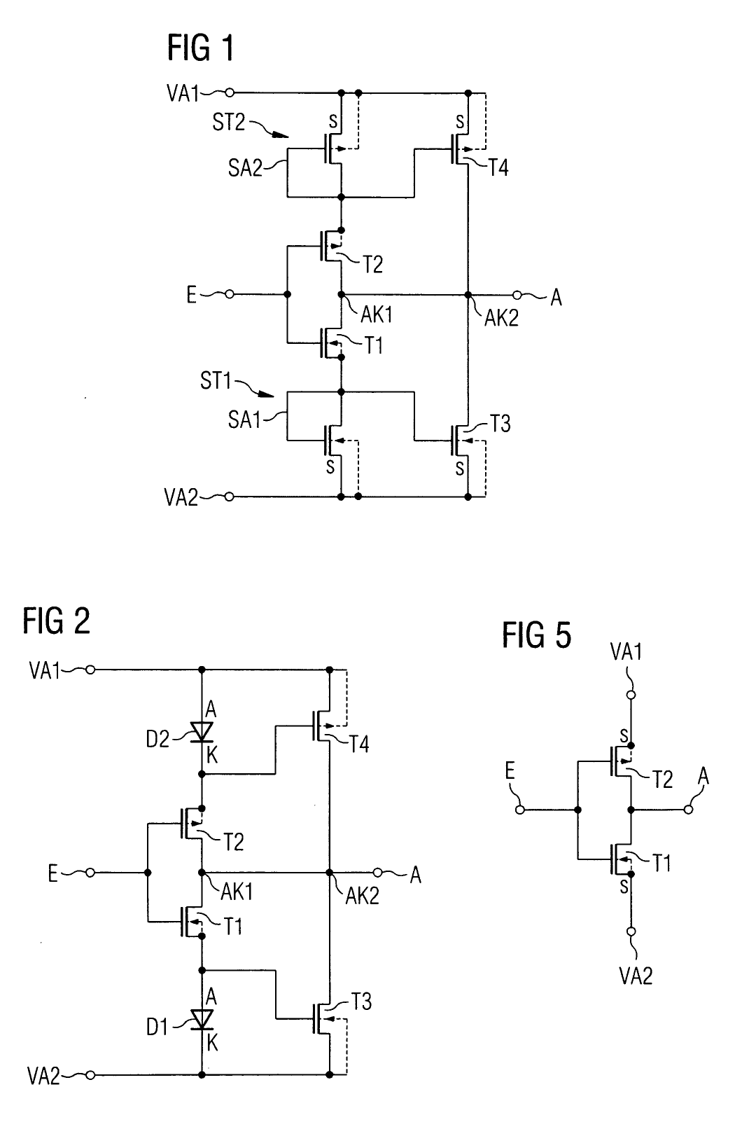

FIG. 1 shows an embodiment of a CMOS buffer embodied with unipolar transistors of complementary channel types. The buffer circuit comprises two supply voltage taps VA1 and VA2, which are embodied for feeding in a supply potential and a reference potential, respectively, for operation of the buffer circuits. The buffer circuit furthermore comprises a signal input E and also a signal output A. The signal input E is coupled to two control terminals of a first transistor pair T1, T2. In other words, the first transistor pair T1, T2 forms an inverter circuit or an auxiliary buffer circuit. The inverter circuit T1, T2 comprises an inverter input coupled to the signal input E, an output node AK1 and a first and a second supply tap. The first transistor T1 is embodied as an n-channel field effect transistor. The second transistor T2 is formed by a p-channel field effect transistor. Their respective sink terminals are coupled to one another at a common node AK1. The two transistors T1, T2 of the first transistor pair furthermore in each case have a substrate terminal coupled, as indicated here, to the source terminal of the respective transistor T1 or T2.

The source terminal of the transistor T1 is coupled to a first controllable path ST1, which is embodied by means of an n-channel field effect transistor in this configuration. The sink terminal of the controllable path ST1, the sink terminal being coupled to the source terminal of the transistor T1, is likewise coupled to the control terminal of the controllable path ST1. The source terminal of the path ST1 is coupled to the supply voltage tap VA2. The transistor of the controllable path ST1 also comprises a substrate terminal coupled to the source terminal of the controllable path ST1.

The controllable path ST2 is configured in the same way. It is coupled with its sink terminal to the source terminal of the transistor T2. The control terminal of the path ST2 is coupled to its sink terminal. The source terminal of the path ST2 is coupled to the supply voltage tap VA1. Different potentials can be applied to the two supply voltage taps VA1 and VA2. By way of example, the ground potential GND is fed to the terminal VA2 and the potential V_{DD} is fed to the terminal VA1. The circuit is thereby supplied with a voltage. At the same time, the levels of the output signals generated during operation of the buffer circuit can be derived from the two potentials.

Consequently, the controllable paths ST1, ST2 and also the first transistor pair with the transistors T1, T2 form a series circuit of field effect transistors, two field effect transistors in each case having the same conductivity type.

A second transistor pair with the transistors T3 and T4 is likewise arranged between the two supply voltage taps VA1, VA2. A node between the two series-connected transistors T3, T4 is coupled to the node AK1 and forms the signal output A of the buffer circuit. The respective source terminals of the transistors T3 and T4 are coupled to the supply voltage tap VA1 and VA2. The control terminal of the transistor T3 is coupled to the sink terminal of the controllable path ST1 and to the source terminal of the transistor T1. The control terminal of the transistor T4 is correspondingly coupled to the source terminal of the transistor T2 and the sink terminal of the second controllable path ST2.

During operation of the buffer circuit, an input signal controls the conductivity of the two transistors T1, T2. As a result, one of the transistors is switched into an on state, and the other into an off state. As a result of this operation, the two paths ST1 and ST2 and also the transistors T3 and T4 are driven correspondingly, so that, depending on the level of the input signal, an inverted level with respect thereto results at the output of the buffer circuit. The level has, in the ideal case, that is to say in the case of vanishing channel resistance of the transistors, the reference potential GND or the supply potential V_{DD}. The changeover instant between the two levels of the output signal can be set in a fault-tolerant manner over a wide range by means of various parameters, for example doping, channel length or else channel width of the individual transistors.

In contrast to the embodiment of a buffer circuit as known from FIG. 5, here a subcircuit comprising three transistors is used instead of a single transistor. This is essentially effected by additionally connecting in parallel the transistor of the second controllable path ST2 and the transistor T4 at the sink terminal of the transistor T2 of the first transistor pair. A parallel circuit is thereby formed. The combination of series and parallel connections of three transistors considerably improves the signal transfer response and also the power consumption compared with the known embodiment from FIG. 5.

Thus, the following value results as the power loss for the embodiment known from FIG. 5:
P_{DIS}=C_{L}V_{DD}²K_{D}f_{CK}
where C_{L} represents the parasitic capacitance, V_{DD} represents the supply voltage and f_{CK} represent the clock frequency of the signal present at the input E. The parameter K_{D} is an additional proportionality factor specifying, inter alia, the duty ratio of the clock frequency f_{CK} of the input signal.

As a result of the feedback of the respective sink terminals to the control terminal of the controllable path ST2 and ST1 as illustrated in FIG. 1, the threshold value V_{T} of the field effect transistors must additionally be taken into account. The maximum voltage is thereby reduced by the respective threshold voltage in the region of 0.5 volts. The power loss in the arrangement according to the invention thus becomes lower and can be expressed by
P_{DISN}=C_{L}(V_{DD}−V_{T})²k_{D}f_{CK}

Given a supply voltage V_{DD}=3.3 volts and a threshold voltage V_{T}=0.5 volts, a ratio between a power loss P_{DISN} of the arrangement according to the invention and the power loss of a known buffer circuit results as P_{DISN}/P_{DIS}=0.72, and hence an improvement by approximately 25%. The lower power loss enables a reduction of the space taken up or a higher signal processing speed in the buffer circuit. At the same time, the reliability in respect of failure and hence also the service life of the buffer circuit are increased.

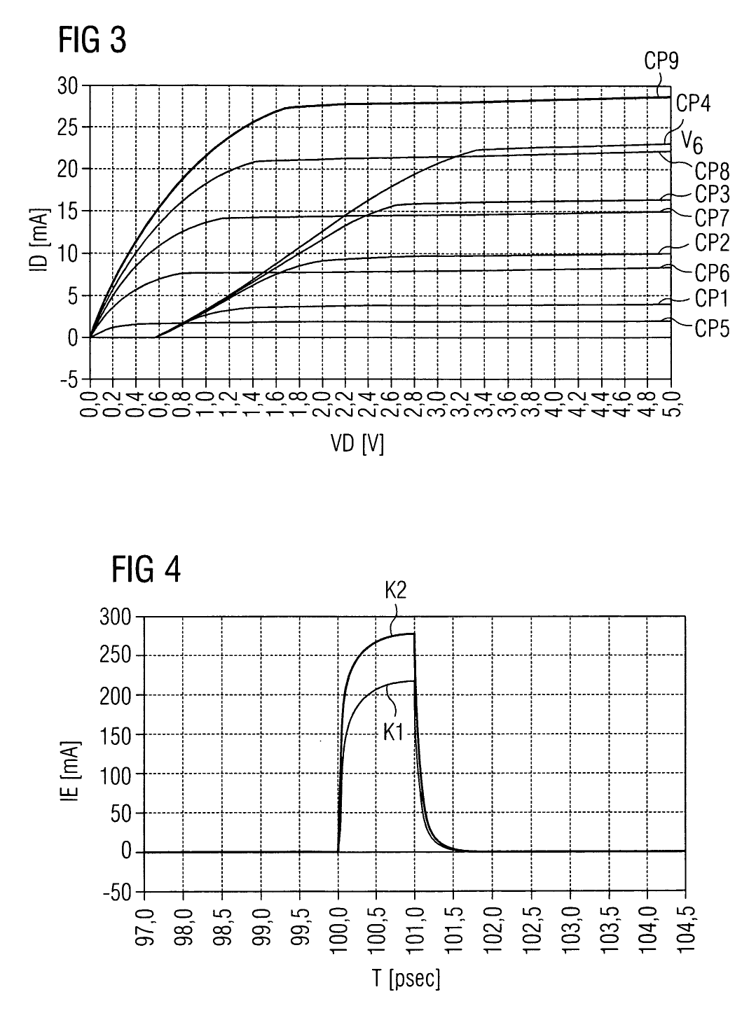

FIG. 3 shows a comparison of the dependencies of the drain current ID with respect to the drain voltage VD for various control voltages VG in the case of the buffer circuit according to one embodiment of the invention and the known CMOS buffer circuit according to FIG. 5. The linear rise in the sink current ID starting at a drain voltage VD of approximately 0.6 volts is clearly discernible in the curves CP1 to CP4. The curves CP1 to CP4 show the profile of the drain current ID for various control voltages VG. The curves CP5 to CP9 correspondingly represent the output characteristic curves for various control voltages in the case of the known embodiment, which have a significantly nonlinear profile in the drain voltage range from 0 V to 3 V.

FIG. 4 elucidates the capacitive behavior of the buffer circuit according to, for example, FIG. 1 in comparison with the known buffer circuit according to FIG. 5. As emerges from the embodiment according to FIG. 1, the total input capacitance of the buffer circuit according the invention is formed by a combination of the capacitance of an individual field effect transistor and a parallel circuit of the capacitances of two further field effect transistors. The total input capacitance is accordingly always less than an input capacitance of an individual field effect transistor. This is confirmed by the diagram illustrated, where a pulsed input signal having an amplitude of 1 V is fed to the circuits. The input currents IE are measured in this case, the curve K1 representing the behavior of the embodiment according to the invention. The curve K2 shows the behavior of the known inverter according to FIG. 5. The lower current flow A is clearly discernible, which indicates a significantly lower input capacitance of the buffer circuit according to the invention.

An application of the arrangement according to the invention is accordingly expedient particularly for circuits that require a low input capacitance. Examples thereof are primarily the input stages of receivers whose input signals have only a very small amplitude, but a poor signal/noise ratio. The lower capacitance reduces charge-reversal effects, whereby the signal processing speed is also improved.

FIG. 2 shows a further embodiment. In this embodiment the controllable paths ST1 and ST2 are replaced by a respective diode D1, D2. In this case, in the diode D1 the cathode terminal K is coupled to the voltage tap VA2. The anode terminal A is coupled to the control terminal of the transistor T3 and to the source terminal of the transistor T1. Correspondingly, the cathode terminal of the diode D2 is coupled to the control terminal of the transistor T4 and the second terminal of the transistor T2 of the first transistor pair. With a modification of the breakdown voltages of the diodes D1, D2 by means of corresponding doping or configuration, it is possible to alter the breakdown voltage of the entire arrangement and also the changeover instant of the arrangement between a high or low output level depending on the input signal level. On account of the various setting parameters of the transistors T1, T3 and the diode D1 and also the transistors T2, T4 and the diode D2, the buffer circuit according to the invention can be optimized to the respectively desired application. In addition, the further parallel connection of diodes or transistors results in an improvement of an electromagnetic compatibility up to a range of several GHz.

Although specific embodiments have been illustrated and described herein, it will be appreciated by those of ordinary skill in the art, that any arrangement that is calculated to achieve the same purpose may be substituted for the specific embodiments shown. It is to be understood, that the above description is intended to be illustrative and not restrictive. This application is intended to cover any adaptations or variations of the invention. Combinations of the above embodiments and many other embodiments will be apparent to those of skill in the art upon reading and understanding the above description. The scope of the invention includes any other embodiments and applications in which the above structures and methods may be used. The scope of the invention should, therefore, be determined with reference to the appended claims along with the scope of equivalents to which such claims are entitled.

It is emphasized that the abstract is provided to comply with 37 C.F.R. § 1.72(b) requiring an abstract that will allow the reader to quickly ascertain the nature and gist of the technical disclosure. It is submitted with the understanding, that it will not be used to interpret or limit the scope or meaning of the claims.

What is claimed is:

1. A buffer circuit, comprising:
a signal input;
a first voltage tap and a second voltage tap;
a first transistor pair comprising a first transistor of a first conductivity type and a series-coupled second transistor of a second conductivity type, control terminals of which are coupled to the signal input;
an output node coupled between the first and second transistors;
a first controllable path of the first conductivity type, which is coupled to the first voltage tap with a first terminal and to its control terminal and to the first transistor with its second terminal;
a second controllable path of the second conductivity type, which is coupled to the second voltage tap with a first terminal and to its control terminal and to the second transistor with its second terminal; and
a second transistor pair comprising a third transistor and a fourth transistor coupled in series, the second transistor pair coupled between the first voltage tap and the second voltage tap, a control terminal of the third transistor coupled to the control terminal of the first controllable path and a control terminal of the fourth transistor coupled to the control terminal of the second controllable path.

2. The buffer circuit as claimed in claim 1, wherein a node coupled between the third and fourth transistor is coupled to the output node.

3. The buffer circuit as claimed in claim 1, wherein the third and the first transistor have the same conductivity type, and wherein the second and the fourth transistor have the same conductivity type.

4. The buffer circuit as claimed in claim 1, wherein the first and second controllable paths each comprise at least one field effect transistor.

5. The buffer circuit as claimed in claim 1, wherein the first transistor comprises a p-channel field effect transistor and the second transistor comprises an n-channel field effect transistor.

6. The buffer circuit as claimed in claim 1, wherein the first transistor comprises a substrate terminal coupled to a source terminal of the first transistor and wherein the second transistor comprises a substrate terminal coupled to a source terminal of the second transistor.

7. The buffer circuit as claimed in claim 1, wherein each of the first, second, third and fourth transistors has a channel length within the range of 60 to 120 nm.

8. A buffer circuit, comprising:
a signal input;
a first transistor pair comprising a first transistor of a first conductivity type and a series-coupled second transistor of a second conductivity type, the control terminals of which are coupled to the signal input;
an output node coupled between the first and second transistors;
a first element having a diode-type transfer response, coupled to the first transistor with an anode terminal;
a second element having a diode-type transfer response, coupled to the second transistor with a cathode terminal; and
a further transistor pair comprising a third transistor and a fourth transistor coupled in series, a control terminal of the third transistor coupled to the anode terminal of the first element and a control terminal of the fourth transistor coupled to the cathode terminal of the second element.

9. The buffer circuit as claimed in claim 8, wherein a node coupled between the third and fourth transistors is coupled to the output node.

10. The buffer circuit as claimed in claim 8, wherein a cathode terminal of the first element is coupled to a first supply voltage tap and an anode terminal of the second element is coupled to a second supply voltage tap.

11. A buffer circuit, comprising:
a signal input;
a first voltage tap and a second voltage tap;
an inverter circuit comprising an inverter input coupled to the signal input, an output node and a first and a second supply tap;
a first controllable path that is coupled to the first voltage tap with a first terminal and to its control terminal and to the first supply tap with its second terminal;
a second controllable path that is coupled to the second voltage tap with a first terminal and to its control terminal and to the second supply tap with its second terminal; and
a transistor pair comprising a first transistor and a second transistor coupled in series, the transistor pair coupled between the first voltage tap and the second voltage tap, a control terminal of the first transistor coupled to the control terminal of the first controllable path and a control terminal of the second transistor coupled to the control terminal of the second controllable path.

12. The buffer circuit as claimed in claim 11, wherein the first controllable path comprises a first conductivity type and the second controllable path comprises a second conductivity type.

13. The buffer circuit as claimed in claim 11, wherein a node coupled between the first and second transistor is coupled to the output node.

14. The buffer circuit as claimed in claim 11, wherein the first controllable path comprises at least one field effect transistor and wherein the second controllable path comprises at least one field effect transistor.

15. The buffer circuit as claimed in claim 11, wherein the inverter circuit comprises a p-channel field effect transistor and an n-channel field effect transistor that is coupled to the p-channel field effect transistor.

16. The buffer circuit as claimed in claim 1, wherein each of the transistors has a channel length within the range of 60 to 120 nm.

17. In a signal processing device for processing logic signals, a buffer circuit for buffering the logic signals, the buffer circuit comprising:
a first transistor pair comprising a first transistor of a first conductivity type and a series-coupled second transistor of a second conductivity type, the control terminals of which are coupled to a signal input to provide a logical input signal;
an output node coupled between the first and second transistors to provide a logical output signal;
a first controllable path of the first conductivity type, which is coupled to a first voltage tap with a first terminal and to its control terminal and to the first transistor with its second terminal;
a second controllable path of the second conductivity type, which is coupled to a second voltage tap with a first terminal and to its control terminal and also to the second transistor with its second terminal; and
a second transistor pair comprising a third transistor and a fourth transistor coupled in series, the second transistor pair coupled between the first voltage tap and the second voltage tap with a control terminal of the third transistor coupled to the control terminal of the first controllable path and a control terminal of the fourth transistor coupled to the control terminal of the second controllable path.
